(19) United States
(12) Patent Application Publication
(10) Pub. No.: US 2015/0280018 A1
(43) Pub. Date: Oct. 1, 2015

(54) PASSIVATION OF LIGHT-RECEIVING SURFACES OF SOLAR CELLS

(71) Applicants: Seung Bum Rim, Palo Alto, CA (US); Genevieve A. Solomon, Palo Alto, CA (US); Michael C. Johnson, Alameda, CA (US); Jérôme Damon-Lacoste, Antony (FR); Antoine Marie Olivier Salomon, Goupillieres (FR)

(72) Inventors: Seung Bum Rim, Palo Alto, CA (US); Genevieve A. Solomon, Palo Alto, CA (US); Michael C. Johnson, Alameda, CA (US); Jérôme Damon-Lacoste, Antony (FR); Antoine Marie Olivier Salomon, Goupillieres (FR)

(21) Appl. No.: 14/226,368

(22) Filed: Mar. 26, 2014

(51) Int. Cl. H01L 31/0216; H01L 31/20; H01L 31/18; H01L 31/068

(52) U.S. Cl. CPC H01L 31/02167; H01L 31/02168; H01L 31/068; H01L 31/202; H01L 31/1868

(57) ABSTRACT

Methods of passivating light-receiving surfaces of solar cells, and the resulting solar cells, are described. In an example, a solar cell includes a silicon substrate having a light-receiving surface. An intrinsic silicon layer is disposed above the light-receiving surface of the silicon substrate. An N-type silicon layer is disposed on the intrinsic silicon layer. A non-conductive anti-reflective coating (ARC) layer is disposed on the N-type silicon layer. In another example, a solar cell includes a silicon substrate having a light-receiving surface. A tunneling dielectric layer is disposed on the light-receiving surface of the silicon substrate. An N-type silicon layer is disposed on the tunneling dielectric layer. A non-conductive anti-reflective coating (ARC) layer is disposed on the N-type silicon layer.

### TECHNICAL FIELD

Embodiments of the present disclosure are in the field of renewable energy and, in particular, methods of passivating light-receiving surfaces of solar cells, and the resulting solar cells.

### BACKGROUND

Photovoltaic cells, commonly known as solar cells, are well known devices for direct conversion of solar radiation into electrical energy. Generally, solar cells are fabricated on a semiconductor wafer or substrate using semiconductor processing techniques to form a p-n junction near a surface of the substrate. Solar radiation impinging on the surface of, and entering into, the substrate creates electron and hole pairs in the bulk of the substrate. The electron and hole pairs migrate to p-doped and n-doped regions in the substrate, thereby generating a voltage differential between the doped regions. The doped regions are connected to conductive regions on the solar cell to direct an electrical current from the cell to an external circuit coupled thereto.

Efficiency is an important characteristic of a solar cell as it is directly related to the capability of the solar cell to generate power. Likewise, efficiency in producing solar cells is directly related to the cost effectiveness of such solar cells. Accordingly, techniques for increasing the efficiency of solar cells, or techniques for increasing the efficiency in the manufacture of solar cells, are generally desirable. Some embodiments of the present disclosure allow for increased solar cell manufacture efficiency by providing novel processes for fabricating solar cell structures. Some embodiments of the present disclosure allow for increased solar cell efficiency by providing novel solar cell structures.

### BRIEF DESCRIPTION OF THE DRAWINGS

FIGS. 1A-1E illustrate cross-sectional views of various stages in the fabrication of a solar cell, in accordance with an embodiment of the present disclosure, wherein:

FIG. 1A illustrates a starting substrate of a solar cell;

FIG. 1B illustrates the structure of FIG. 1A following formation of a tunneling dielectric layer on a light-receiving surface of the substrate;

FIG. 1C illustrates the structure of FIG. 1B following formation of an intrinsic silicon layer on the tunneling dielectric layer;

FIG. 1D illustrates the structure of FIG. 1C following formation of an N-type silicon layer on the intrinsic silicon layer; and

FIG. 1E illustrates the structure of FIG. 1D following formation of a non-conductive anti-reflective coating (ARC) layer on the N-type silicon layer.

FIG. 2 is a flowchart listing operations in a method of fabricating a solar cell as corresponding to FIGS. 1A-1E, in accordance with an embodiment of the present disclosure.

FIG. 3 illustrates a cross-sectional view of a back-contact solar cell having emitter regions formed above a back surface of a substrate and having a first exemplary stack of layers on a light-receiving surface of the substrate, in accordance with an embodiment of the present disclosure.

FIG. 4 illustrates a cross-sectional view of a back-contact solar cell having emitter regions formed in a back surface of a substrate and having the first exemplary stack of layers on a light-receiving surface of the substrate, in accordance with an embodiment of the present disclosure.

FIG. 5 is an energy band diagram for the first exemplary stack of layers disposed on a light-receiving surface of the solar cells described in association with FIGS. 3 and 4, in accordance with an embodiment of the present disclosure.

FIG. 6A illustrates a cross-sectional view of a back-contact solar cell having emitter regions formed above a back surface of a substrate and having a second exemplary stack of layers on a light-receiving surface of the substrate, in accordance with an embodiment of the present disclosure.

FIG. 6B is an energy band diagram for the second exemplary stack of layers disposed on a light-receiving surface of the solar cell described in association with FIG. 6A, in accordance with an embodiment of the present disclosure.

FIG. 7A illustrates a cross-sectional view of a back-contact solar cell having emitter regions formed above a back surface of a substrate and having a third exemplary stack of layers on a light-receiving surface of the substrate, in accordance with an embodiment of the present disclosure.

FIG. 7B is an energy band diagram for the third exemplary stack of layers disposed on a light-receiving surface of the solar cell described in association with FIG. 7A, in accordance with an embodiment of the present disclosure.

FIG. 8 is an energy band diagram for a light-receiving surface of a prior art solar cell.

### DETAILED DESCRIPTION

The following detailed description is merely illustrative in nature and is not intended to limit the embodiments of the subject matter or the application and uses of such embodiments. As used herein, the word “exemplary” means “serving as an example, instance, or illustration.” Any implementation described herein as exemplary is not necessarily to be construed as preferred or advantageous over other implementations. Furthermore, there is no intention to be bound by any expressed or implied theory presented in the preceding technical field, background, brief summary or the following detailed description.

This specification includes references to “one embodiment” or “an embodiment.” The appearances of the phrases “in one embodiment” or “in an embodiment” do not necessarily refer to the same embodiment. Particular features, structures, or characteristics may be combined in any suitable manner consistent with this disclosure.

Terminology. The following paragraphs provide definitions and/or context for terms found in this disclosure (including the appended claims):

“Comprising.” This term is open-ended. As used in the appended claims, this term does not foreclose additional structure or steps.

“Configured To.” Various units or components may be described or claimed as “configured to” perform a task or tasks. In such contexts, “configured to” is used to connote structure by indicating that the units/components include structure that performs those task or tasks during operation. As such, the unit/component can be said to be configured to perform the task even when the specified unit/component is not currently operational (e.g., is not on/active). Reciting that a unit/circuit/component is “configured to” perform one or more tasks is expressly intended not to invoke 35 U.S.C. §112, sixth paragraph, for that unit/component.

“First,”, “Second,” etc. As used herein, these terms are used as labels for nouns that they precede, and do not imply any type of ordering (e.g., spatial, temporal, logical, etc.). For example, reference to a “first” solar cell does not necessarily imply that this solar cell is the first solar cell in a sequence; instead the term “first” is used to differentiate this solar cell from another solar cell (e.g., a “second” solar cell).

“Coupled”—The following description refers to elements or nodes or features being “coupled” together. As used herein, unless expressly stated otherwise, “coupled” means that one element/node/feature is directly or indirectly joined to (or directly or indirectly communicates with) another element/node/feature, and not necessarily mechanically.

In addition, certain terminology may also be used in the following description for the purpose of reference only, and thus are not intended to be limiting. For example, terms such as “upper”, “lower”, “above”, and “below” refer to directions in the drawings to which reference is made. Terms such as “front”, “back”, “rear”, “side”, “outboard”, and “inboard” describe the orientation and/or location of portions of the component within a consistent but arbitrary frame of reference which is made clear by reference to the text and the associated drawings describing the component under discussion. Such terminology may include the words specifically mentioned above, derivatives thereof, and words of similar import.

Methods of passivating light-receiving surfaces of solar cells, and the resulting solar cells, are described herein. In the following description, numerous specific details are set forth, such as specific process flow operations, in order to provide a thorough understanding of embodiments of the present disclosure. It will be apparent to one skilled in the art that embodiments of the present disclosure may be practiced without these specific details. In other instances, well-known fabrication techniques, such as lithography and patterning techniques, are not described in detail in order to not unnecessarily obscure embodiments of the present disclosure. Furthermore, it is to be understood that the various embodiments shown in the figures are illustrative representations and are not necessarily drawn to scale.

Disclosed herein are solar cells. In one embodiment, a solar cell includes a silicon substrate having a light-receiving surface. An intrinsic silicon layer is disposed above the light-receiving surface of the silicon substrate. An N-type silicon layer is disposed on the intrinsic silicon layer. A non-conductive anti-reflective coating (ARC) layer is disposed on the N-type silicon layer.

In another embodiment, a solar cell includes a silicon substrate having a light-receiving surface. A tunneling dielectric layer is disposed on the light-receiving surface of the silicon substrate. An N-type silicon layer is disposed on the tunneling dielectric layer. A non-conductive anti-reflective coating (ARC) layer is disposed on the N-type silicon layer.

Also disclosed herein are methods of fabricating solar cells. In one embodiment, a method of fabricating a solar cell involves forming a tunneling dielectric layer on a light-receiving surface of a silicon substrate. The method also involves forming an amorphous silicon layer on the tunneling dielectric layer at a temperature less than approximately 300 degrees Celsius.

One or more embodiments described herein are directed to low temperature passivation approaches for improved (mitigation of) light induced degradation (LID). More particularly, several approaches are described for improving ultra-violet (UV) stability of the front surface of a low-temperature passivated cell, e.g., for cases where an amorphous silicon (aSi) material is used to passivate the crystalline silicon (c-Si) substrate surface. For example, by modifying the structure and employing new passivation material stacks, improvements in the stability of such cells employing can be achieved as pertaining to long term energy generation.

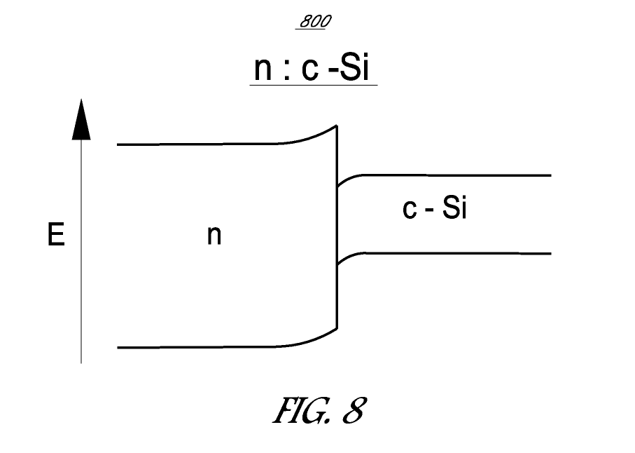

To provide context, light induced degradation is a major problem for aSi passivated c-Si surfaces, especially when exposed to high energy photons (e.g., UV photons). Rapid degradation can take place even under the most benign conditions due to the unstable nature of the c-Si/aSi interface. FIG. 8 is an energy band diagram 800 for a light-receiving surface of a prior art solar cell c-Si/a-Si interface which is a heterojunction. Referring to FIG. 8, an N-type hydrogenated amorphous silicon (n a-Si) and crystalline silicon (c-Si) interface in a light-receiving surface of a solar cell has proven to provide poor passivation, leading to instability and ready degradation. The poor passivation exhibited is understood to derive from large recombination sites introduced by the phosphorous (P) dopant source at the interface. Attempts to provide a front surface (light-receiving surface) of a solar cell stable without the use of high temperature operations has proven challenging. For example, previous attempts have included the use of thermal diffusion followed by a thermal oxidation process and a subsequent high temperature plasma-enhanced chemical vapor deposition (PECVD) processes in excess of 380 degrees Celsius. Under such conditions, poor passivation has been achieved. By contrast, if thin silicon (Si) processes could be performed at temperatures below 300 degrees Celsius, the materials of carriers of the wafers used to support the base cells can be accommodated.

In accordance with one or more embodiments described herein, passivation approaches for a light-receiving surface of a solar cell include one or more of: (1) using a thin oxide material formed at low temperature (e.g., a chemical oxide, a PECVD-formed oxide, a low temperature thermal oxide, or an ultra-violet/ozone (UV/O₃)-formed oxide) for improved stability; (2) employing an intrinsic hydrogenated amorphous silicon/N-type amorphous silicon (a-Si:i/a-Si:n) stack as the passivating layer and utilizing the electronic characteristics of a phosphorous-doped a-Si layer to bend the electronic bands for improved shielding of recombination sites at the surface; (3) depositing a phosphorous-diffused epitaxial layer on a textured surface to help improve stability by repelling minority carriers away from the c-Si/a-Si interface; 4) a burn-in method of exposing the front surface to a UV dose followed by a low temperature anneal to harden the interface; and (5) a simplified cleaning procedure of a dilute hydrofluoric acid/ozone (HF/O₃) in deionized water (DI) for providing a manufacturing friendly process. One or more, or all, of the above listed approaches may be combined for use on a suitable front surface stack for maximum transparency (Jsc) and suitable and stable passivation (Voc).

In a specific exemplary embodiment, a simplified cleaning process using 0.3% HF/O₃ followed by a DI rinse and HW dryer were employed to obtain good passivation of less than approximately 10 fA/cm² for structures deposited at 200 degrees Celsius (e.g., aSi:i/SiN aSi:i/aSi:n/SiN structures) on textured substrates. In other embodiments, more aggressive chemistries such as HF/Piranha (sulfuric acid an hydrogen peroxide)/HF mixtures or HF-only also exhibited similar passivation values. Upon testing with exposure to high intensity UV, the simplified cleaning procedure samples performed better. Although not to be bound by theory, it is presently understood that the improvements stemmed from the formation of a thin chemical oxide formed that did not inhibit initial passivation and reduced degradation by stabilizing the resulting interface passivation. It has been discovered that such an oxide material can be deposited in a variety of ways, as mentioned above.

More generally, in accordance with one or more embodiments, an intrinsic (possibly hydrogenated) amorphous silicon:N-type amorphous silicon (represented as i:n) structure is fabricated with or without a thin oxide for improved passivation. In another embodiment, the N-type amorphous silicon layer can be used alone, so long as the thin oxide is of sufficiently high quality to maintain good passivation. In cases where an intrinsic amorphous silicon is implemented, the material provides an additional passivation protection in case of a defective oxide. In other embodiment, inclusion of a phosphorous-doped amorphous silicon layer in addition to the intrinsic layer improves stability against UV degradation. The phosphorous-doped layer can be implemented to enable band-bending which aids in shielding the interface by repelling the minority carriers reducing the amount of recombination.

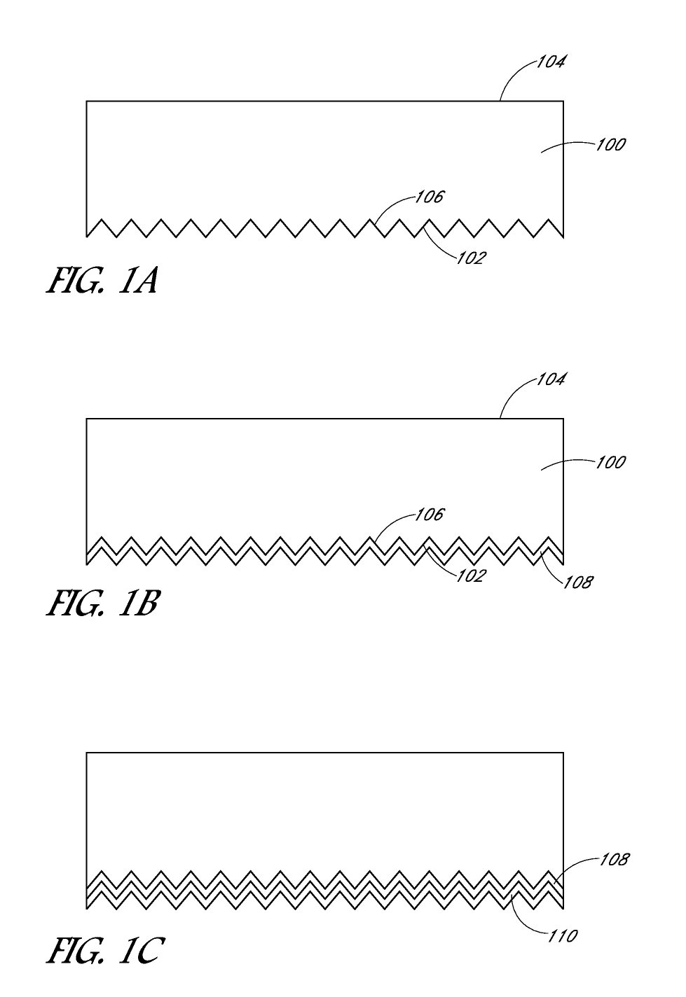

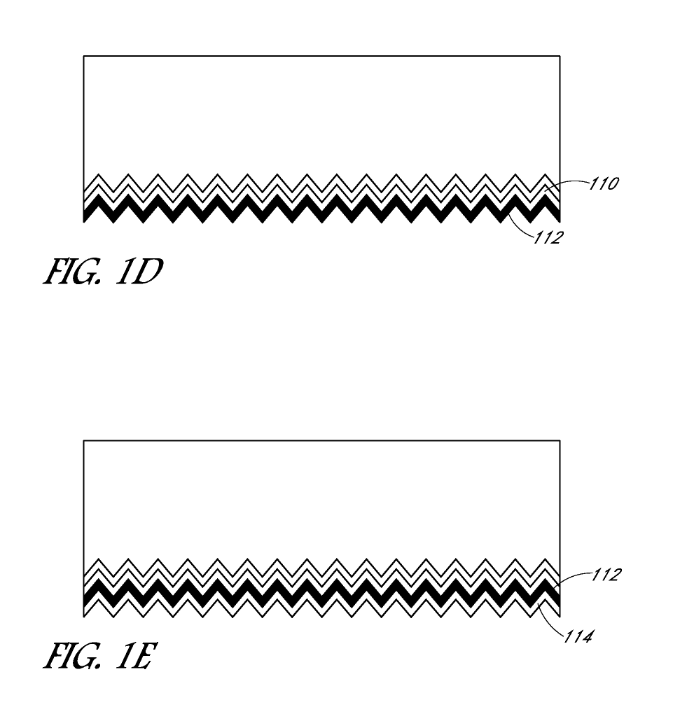

FIGS. 1A-1E illustrate cross-sectional views of various stages in the fabrication of a solar cell, in accordance with an embodiment of the present disclosure. FIG. 2 is a flowchart listing operations in a method of fabricating a solar cell as corresponding to FIGS. 1A-1E, in accordance with an embodiment of the present disclosure.

FIG. 1A illustrates a starting substrate of a solar cell. Referring to FIG. 1A, substrate 100 has a light-receiving surface 102 and a back surface 104. In an embodiment, the substrate 100 is a monocrystalline silicon substrate, such as a bulk single crystalline N-type doped silicon substrate. It is to be appreciated, however, that substrate 100 may be a layer, such as a multi-crystalline silicon layer, disposed on a global solar cell substrate. In an embodiment, the light-receiving surface 102 has a texturized topography 106. In one such embodiment, a hydroxide-based wet etchant is employed to texturize the front surface of the substrate 100. It is to be appreciated that a texturized surface may be one which has a regular or an irregular shaped surface for scattering incoming light, decreasing the amount of light reflected off of the light-receiving surfaces of the solar cell.

FIG. 1B illustrates the structure of FIG. 1A following formation of a tunneling dielectric layer on a light-receiving surface of the substrate. Referring to FIG. 1B and corresponding operation 202 of flowchart 200, a tunneling dielectric layer 108 is formed on the light-receiving surface 102 of substrate 100. In one embodiment, the light-receiving surface 102 has a texturized topography 106, and the tunneling dielectric layer 108 is conformal with the texturized topography 106, as is depicted in FIG. 1B.

In an embodiment, the tunneling dielectric layer 108 is a layer of silicon dioxide (SiO₂). In one such embodiment, the layer of silicon dioxide (SiO₂) has a thickness approximately in the range of 1-10 nanometers and, preferably, less than 1.5 nanometers. In one embodiment, the tunneling dielectric layer 108 is hydrophilic. In an embodiment, the tunneling dielectric layer 108 is formed by a technique such as, but not limited to, chemical oxidation of a portion of the light-receiving surface of the silicon substrate, plasma-enhanced chemical vapor deposition (PECVD) of silicon dioxide (SiO₂), thermal oxidation of a portion of the light-receiving surface of the silicon substrate, or exposure of the light-receiving surface of the silicon substrate to ultra-violet (UV) radiation in an O₂ or O₃ environment.

FIG. 1C illustrates the structure of FIG. 1B following formation of an intrinsic silicon layer on the tunneling dielectric layer. Referring to FIG. 1C and corresponding operation 204 of flowchart 200, an intrinsic silicon layer 110 is formed on the tunneling dielectric layer 108.

In an embodiment, the intrinsic silicon layer 110 is an intrinsic amorphous silicon layer. In one such embodiment, the intrinsic amorphous silicon layer has a thickness approximately in the range of 1-5 nanometers. In one embodiment, forming the intrinsic amorphous silicon layer on the tunneling dielectric layer 108 is performed at a temperature less than approximately 300 degrees Celsius. In an embodiment, the intrinsic amorphous silicon layer is formed using plasma enhanced chemical vapor deposition (PECVD), represented by a-Si:H, which includes Si—H covalent bonds throughout the layer.

FIG. 1D illustrates the structure of FIG. 1C following formation of an N-type silicon layer on the intrinsic silicon layer. Referring to FIG. 1D and corresponding operation 206 of flowchart 200, an N-type silicon layer 112 is formed on the intrinsic silicon layer 110.

In an embodiment, the N-type silicon layer 112 is an N-type amorphous silicon layer. In one embodiment, forming the N-type amorphous silicon layer on the intrinsic silicon layer 110 is performed at a temperature less than approximately 300 degrees Celsius. In an embodiment, the N-type amorphous silicon layer is formed using plasma enhanced chemical vapor deposition (PECVD), represented by phosphorous-doped a-Si:H, which includes Si—H covalent bonds throughout the layer. In one embodiment, the N-type silicon layer 112 includes an impurity such as phosphorous dopants. In one embodiment, the phosphorous dopants are incorporated either during film deposition or in a post implantation operation.

FIG. 1E illustrates the structure of FIG. 1D following formation of a non-conductive anti-reflective coating (ARC) layer on the N-type silicon layer. Referring to FIG. 1E and corresponding operation 208 of flowchart 200, a non-conductive anti-reflective coating (ARC) layer 114 is formed on the N-type silicon layer 112. In an embodiment, the non-conductive ARC layer includes silicon nitride. In one such embodiment, the silicon nitride is formed at a temperature less than approximately 300 degrees Celsius.

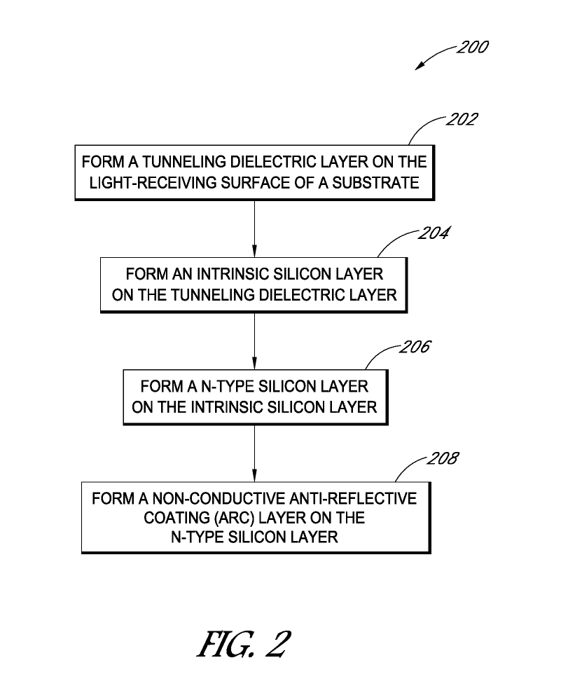

FIG. 3 illustrates a cross-sectional view of a back-contact solar cell having emitter regions formed above a back surface of a substrate and having a first exemplary stack of layers on a light-receiving surface of the substrate, in accordance with an embodiment of the present disclosure.

Referring to FIG. 3, a solar cell includes a silicon substrate 100 having a light-receiving surface 102. A tunneling dielectric layer 108 is disposed on the light-receiving surface of the silicon substrate 100. An intrinsic silicon layer 110 is disposed on the tunneling dielectric layer 108. An N-type silicon layer 112 is disposed on the intrinsic silicon layer 110. A non-conductive anti-reflective coating (ARC) layer 114 is disposed on the N-type silicon layer 112. As such, the stack of layers on the light-receiving surface of the solar cell of FIG. 3 is the same as that described in association with FIG. 1A-1E.

Referring again to FIG. 3, on the back surface of the substrate 100, alternating P-type 120 and N-type 122 emitter regions are formed. In one such embodiment, trenches 121 are disposed between the alternating P-type 120 and N-type 122 emitter regions. More particularly, in an embodiment, first polycrystalline silicon emitter regions 122 are formed on a first portion of a thin dielectric layer 124 and are doped with an N-type impurity. Second polycrystalline silicon emitter regions 120 are formed on a second portion of the thin dielectric layer 124 and are doped with a P-type impurity. In an embodiment the tunnel dielectric 124 is a silicon oxide layer having a thickness of approximately 2 nanometers or less.

Referring again to FIG. 3, conductive contact structures 128/130 are fabricated by first depositing and patterning an insulating layer 126 to have openings and then forming one or more conductive layers in the openings. In an embodiment, the conductive contact structures 128/130 include metal and are formed by a deposition, lithographic, and etch approach or, alternatively, a printing or plating process or, alternatively, a foil adhesion process.

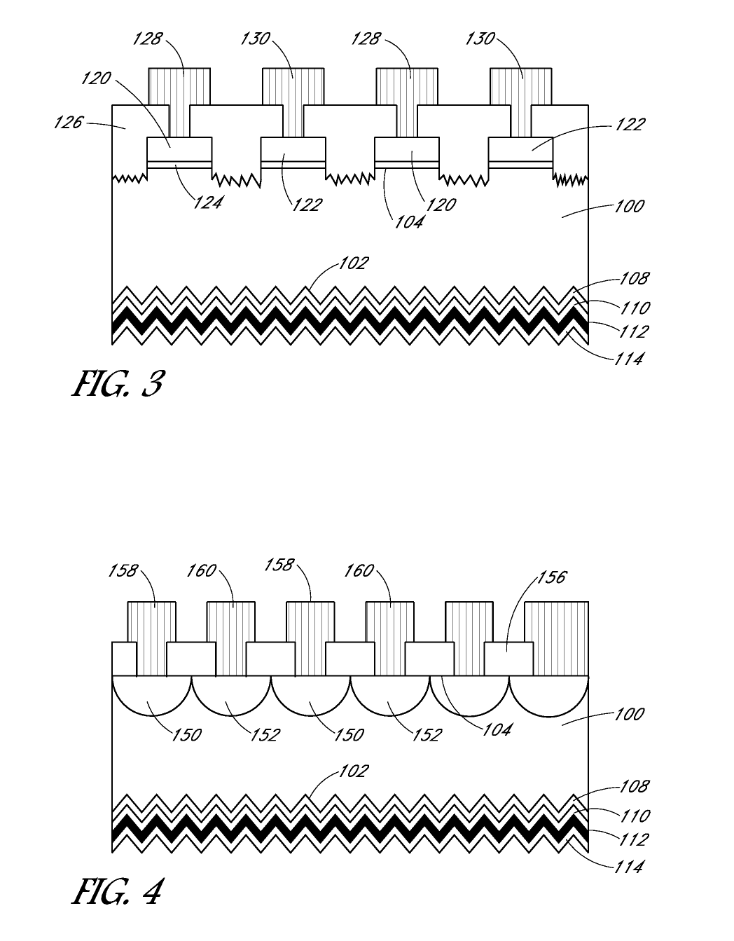

FIG. 4 illustrates a cross-sectional view of a back-contact solar cell having emitter regions formed in a back surface of a substrate and having the first exemplary stack of layers on a light-receiving surface of the substrate, in accordance with an embodiment of the present disclosure.

Referring to FIG. 4, a solar cell includes a silicon substrate 100 having a light-receiving surface 102. A tunneling dielectric layer 108 is disposed on the light-receiving surface of the silicon substrate 100. An intrinsic silicon layer 110 is disposed on the tunneling dielectric layer 108. An N-type silicon layer 112 is disposed on the intrinsic silicon layer 110. A non-conductive anti-reflective coating (ARC) layer 114 is disposed on the N-type silicon layer 112. As such, the stack of layers on the light-receiving surface of the solar cell of FIG. 4 is the same as that described in association with FIG. 1A-1E.

Referring again to FIG. 4, within the back surface of the substrate 100, alternating P-type 150 and N-type 152 emitter regions are formed. More particularly, in an embodiment, first emitter regions 152 are formed within a first portion of substrate 100 and are doped with an N-type impurity. Second emitter regions 150 are formed within a second portion of substrate 100 and are doped with a P-type impurity. Referring again to FIG. 4, conductive contact structures 158/160 are fabricated by first depositing and patterning an insulating layer 156 to have openings and then forming one or more conductive layers in the openings. In an embodiment, the conductive contact structures 158/160 include metal and are formed by a deposition, lithographic, and etch approach or, alternatively, a printing or plating process or, alternatively, a foil adhesion process.

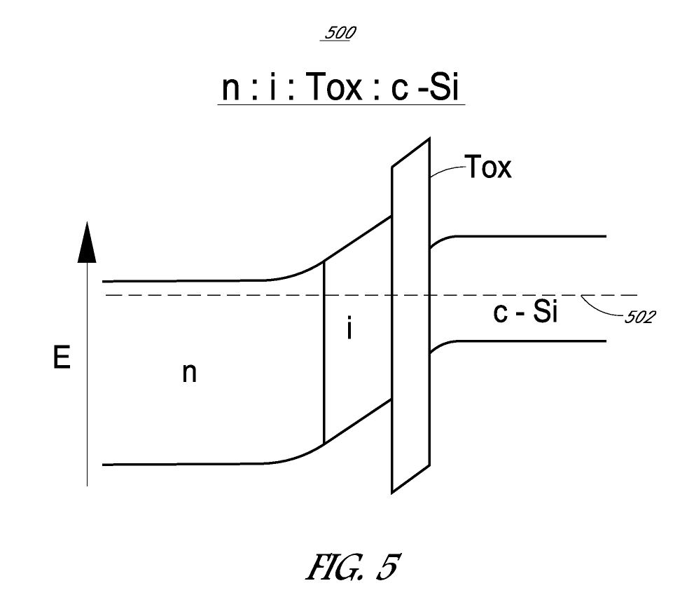

FIG. 5 is an energy band diagram 500 for the first exemplary stack of layers disposed on a light-receiving surface of the solar cells described in association with FIGS. 3 and 4, in accordance with an embodiment of the present disclosure. Referring to the energy band diagram 500, a band structure is provided for a material stack including N-type doped silicon (n), intrinsic silicon (i), a thin oxide layer (Tox), and the crystalline silicon substrate (c-Si). The Fermi level is shown at 502 and reveals good passivation of the light-receiving surface of a substrate having this material stack.

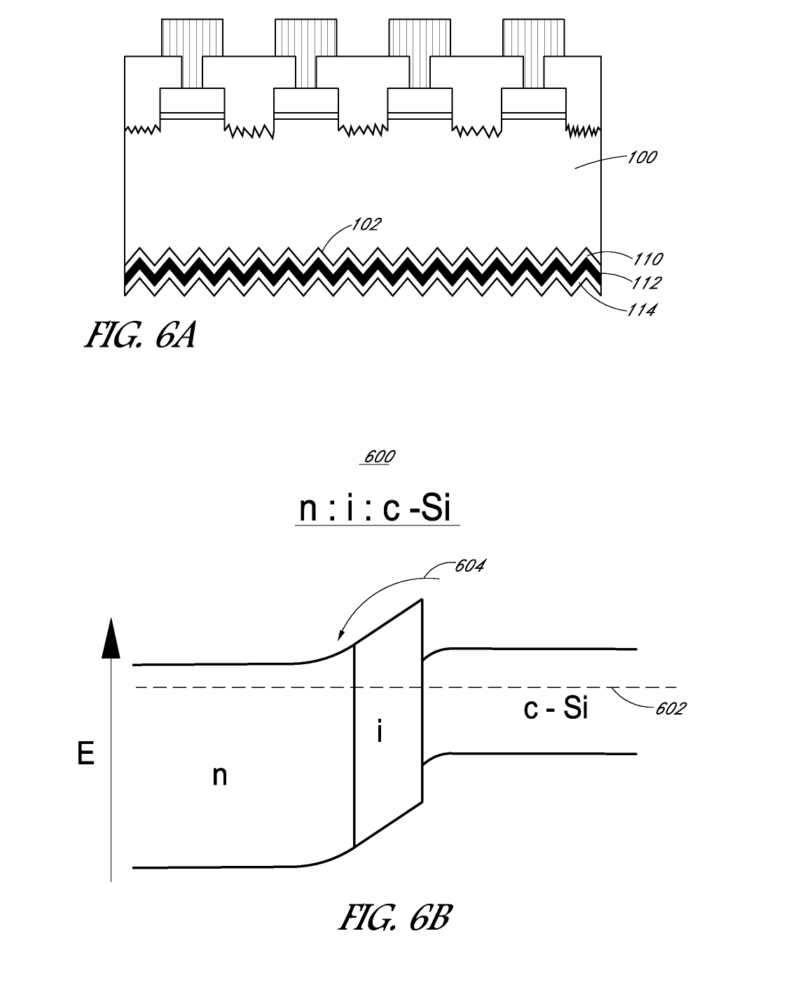

FIG. 6A illustrates a cross-sectional view of a back-contact solar cell having emitter regions formed above a back surface of a substrate and having a second exemplary stack of layers on a light-receiving surface of the substrate, in accordance with an embodiment of the present disclosure.

Referring to FIG. 6A, a solar cell includes a silicon substrate 100 having a light-receiving surface 102. An intrinsic silicon layer 110 is disposed on the light-receiving surface 102 of the silicon substrate 100 (in this case, the growth may be epitaxial). An N-type silicon layer 112 is disposed on the intrinsic silicon layer 110. A non-conductive anti-reflective coating (ARC) layer 114 is disposed on the N-type silicon layer 112. As such, the stack of layers on the light-receiving surface of the solar cell of FIG. 6A does not include the tunneling dielectric layer 108 described in association with FIG. 3. Other features described in association with FIG. 3, however, are similar. Furthermore, it is to be appreciated that emitter region may be formed within the substrate, as described in association with FIG. 4.

FIG. 6B is an energy band diagram 600 for the second exemplary stack of layers disposed on a light-receiving surface of the solar cell described in association with FIG. 6A, in accordance with an embodiment of the present disclosure. Referring to the energy band diagram 600, a band structure is provided for a material stack including N-type doped silicon (n), intrinsic silicon (i), and a crystalline silicon substrate (c-Si). The Fermi level is shown at 602 and reveals good passivation of the light-receiving surface of a substrate having this material stack even though an oxide layer is not in place to block pathway 604.

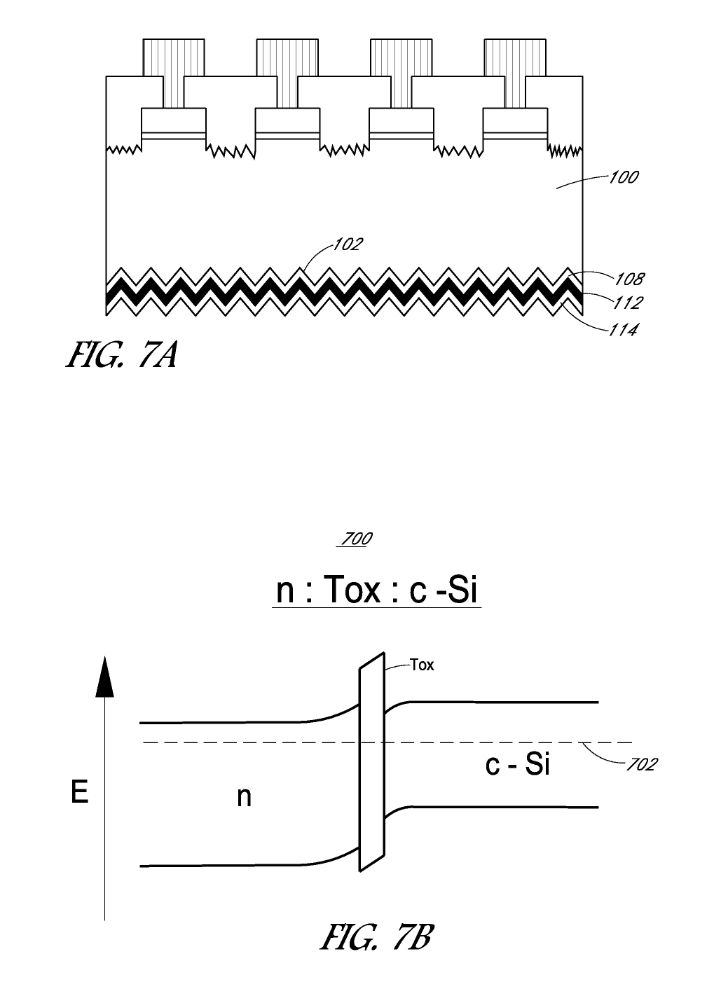

FIG. 7A illustrates a cross-sectional view of a back-contact solar cell having emitter regions formed above a back surface of a substrate and having a third exemplary stack of layers on a light-receiving surface of the substrate, in accordance with an embodiment of the present disclosure.

Referring to FIG. 7A, a solar cell includes a silicon substrate 100 having a light-receiving surface 102. A tunneling dielectric layer 108 is disposed on the light-receiving surface 102 of the silicon substrate 100. An N-type silicon layer 112 is disposed on the tunneling dielectric layer 108. A non-conductive anti-reflective coating (ARC) layer 114 is disposed on the N-type silicon layer 112. As such, the stack of layers on the light-receiving surface of the solar cell of FIG. 7A does not include the intrinsic silicon layer 110 described in association with FIG. 3. Other features described in association with FIG. 3, however, are similar. Furthermore, it is to be appreciated that emitter region may be formed within the substrate, as described in association with FIG. 4.

FIG. 7B is an energy band diagram 700 for the third exemplary stack of layers disposed on a light-receiving surface of the solar cell described in association with FIG. 7A, in accordance with an embodiment of the present disclosure. Referring to the energy band diagram 700, a band structure is provided for a material stack including N-type doped silicon (n), a thin oxide layer (Tox), and the crystalline silicon substrate (c-Si). The Fermi level is shown at 702 and reveals good passivation of the light-receiving surface of a substrate having this material stack.

Overall, although certain materials are described specifically above, some materials may be readily substituted with others with other such embodiments remaining within the spirit and scope of embodiments of the present disclosure. For example, in an embodiment, a different material substrate, such as a group III-V material substrate, can be used instead of a silicon substrate. Furthermore, it is to be understood that, where N+ and P+ type doping is described specifically for emitter regions on a back surface of a solar cell, other embodiments contemplated include the opposite conductivity type, e.g., P+ and N+ type doping, respectively.

Thus, methods of passivating light-receiving surfaces of solar cells, and the resulting solar cells, have been disclosed.

Although specific embodiments have been described above, these embodiments are not intended to limit the scope of the present disclosure, even where only a single embodiment is described with respect to a particular feature. Examples of features provided in the disclosure are intended to be illustrative rather than restrictive unless stated otherwise. The above description is intended to cover such alternatives, modifications, and equivalents as would be apparent to a person skilled in the art having the benefit of this disclosure.

The scope of the present disclosure includes any feature or combination of features disclosed herein (either explicitly or implicitly), or any generalization thereof, whether or not it mitigates any or all of the problems addressed herein. Accordingly, new claims may be formulated during prosecution of this application (or an application claiming priority thereto) to any such combination of features. In particular, with reference to the appended claims, features from dependent claims may be combined with those of the independent claims and features from respective independent claims may be combined in any appropriate manner and not merely in the specific combinations enumerated in the appended claims.

What is claimed is:

1. A solar cell, comprising:
a silicon substrate having a light-receiving surface;
an intrinsic silicon layer disposed above the light-receiving surface of the silicon substrate;
an N-type silicon layer disposed on the intrinsic silicon layer; and
a non-conductive anti-reflective coating (ARC) layer disposed on the N-type silicon layer.

2. The solar cell of claim 1, wherein the silicon substrate is a monocrystalline silicon substrate, wherein the intrinsic silicon layer is an intrinsic amorphous silicon layer, and wherein the N-type silicon layer is an N-type amorphous silicon layer.

3. The solar cell of claim 1, further comprising:
a tunneling dielectric layer disposed on the light-receiving surface of the silicon substrate, wherein the intrinsic silicon layer is disposed on the tunneling dielectric layer.

4. The solar cell of claim 3, wherein the tunneling dielectric layer is a layer of silicon dioxide (SiO₂).

5. The solar cell of claim 4, wherein the silicon substrate is a monocrystalline silicon substrate, wherein the intrinsic silicon layer is an intrinsic amorphous silicon layer, and wherein the N-type silicon layer is an N-type amorphous silicon layer.

6. The solar cell of claim 5, wherein the layer of silicon dioxide (SiO₂) has a thickness approximately in the range of 1-10 nanometers, and wherein the intrinsic amorphous silicon layer has a thickness approximately in the range of 1-5 nanometers.

7. The solar cell of claim 1, wherein the non-conductive anti-reflective coating (ARC) layer comprises silicon nitride.

8. The solar cell of claim 1, wherein the light-receiving surface has a texturized topography, and wherein the intrinsic silicon layer is conformal with the texturized topography of the light-receiving surface.

9. The solar cell of claim 1, wherein the substrate further comprises a back surface opposite the light-receiving surface, the solar cell further comprising:
a plurality of alternating N-type and P-type semiconductor regions at or above the back surface of the substrate; and
a conductive contact structure coupled to the plurality of alternating N-type and P-type semiconductor regions.

10. A solar cell, comprising:
a silicon substrate having a light-receiving surface;
a tunneling dielectric layer disposed on the light-receiving surface of the silicon substrate;
an N-type silicon layer disposed on the tunneling dielectric layer; and
a non-conductive anti-reflective coating (ARC) layer disposed on the N-type silicon layer.

11. The solar cell of claim 10, wherein the silicon substrate is a monocrystalline silicon substrate, and wherein the N-type silicon layer is an N-type amorphous silicon layer.

12. The solar cell of claim 10, wherein the tunneling dielectric layer is a layer of silicon dioxide (SiO₂) having a thickness approximately in the range of 1-10 nanometers.

13. The solar cell of claim 10, wherein the non-conductive anti-reflective coating (ARC) layer comprises silicon nitride.

14. The solar cell of claim 10, wherein the light-receiving surface of the substrate has a texturized topography, and wherein the N-type silicon layer is conformal with the texturized topography of the light-receiving surface.

15. The solar cell of claim 10, wherein the substrate further comprises a back surface opposite the light-receiving surface, the solar cell further comprising:
a plurality of alternating N-type and P-type semiconductor regions at or above the back surface of the substrate; and
a conductive contact structure coupled to the plurality of alternating N-type and P-type semiconductor regions.

16. A method of fabricating a solar cell, the method comprising:
forming a tunneling dielectric layer on a light-receiving surface of a silicon substrate; and
forming an amorphous silicon layer on the tunneling dielectric layer at a temperature less than approximately 300 degrees Celsius.

17. The method of claim 16, wherein forming the tunneling dielectric layer comprises using a technique selected from the group consisting of chemical oxidation of a portion of the light-receiving surface of the silicon substrate, plasma-enhanced chemical vapor deposition (PECVD) of silicon dioxide (SiO₂), thermal oxidation of a portion of the light-receiving surface of the silicon substrate, and exposure of the light-receiving surface of the silicon substrate to ultra-violet (UV) radiation in an O₂ or O₃ environment.

18. The method of claim 16, wherein forming the amorphous silicon layer comprises forming an intrinsic amorphous silicon layer, the method further comprising:
forming an N-type amorphous silicon layer on the amorphous silicon layer at a temperature less than approximately 300 degrees Celsius; and
forming an anti-reflective coating (ARC) layer on the N-type amorphous silicon layer at a temperature less than approximately 300 degrees Celsius.

19. The method of claim 16, wherein forming the amorphous silicon layer comprises forming an N-type amorphous silicon layer, the method further comprising:
forming an anti-reflective coating (ARC) layer on the N-type amorphous silicon layer at a temperature less than approximately 300 degrees Celsius.

20. A solar cell fabricated according to the method of claim 16.
